(19) United States
(12) Patent Application Publication
(10) Pub. No.: US 2024/0198451 A1
(43) Pub. Date: Jun. 20, 2024

(54) FIBER OUTPUT HYBRID LASER SYSTEM

(71) Applicant: TURNING POINT LASERS CORPORATION, HSINCHU CITY (TW)

(72) Inventors: CHI LUEN WANG, HSINCHU CITY (TW); HUNG SHENG LEE, TAIPEI CITY (TW); YI SHIN SU, HSINCHU COUNTY (TW); SHIH WEI LIN, TAOYUAN CITY (TW); SZUTSUN SIMON OU, TAIPEI CITY (TW)

(21) Appl. No.: 18/068,846

(22) Filed: Dec. 20, 2022

(51) Int. Cl. B23K 26/06; G02B 6/04; G02B 6/26; H01S 3/094; H01S 3/0941; H01S 5/02251; H01S 5/40

(52) U.S. Cl. CPC B23K 26/0617; G02B 6/04; G02B 6/262; H01S 3/094003; H01S 3/09415; H01S 5/02251; H01S 5/4012; H01S 5/4025

(57) ABSTRACT

A fiber output hybrid laser system, which having at least a blue ray laser model, emitting a blue ray laser beam; an infrared optic fiber laser module, emitting an infrared laser beam; a fiber bundle combining the above mentioned two laser beams, an output optical assembly collimating the laser beams, and generating focal points of two wavelengths; wherein the blue ray laser beam and the infrared laser beam which are coaxial and coincident to emit light, and the BPP of the blue ray laser beam and the infrared laser beam are both less than 10 mm*mrad; the power of the blue ray laser beam is between 20˜100 W, the power of the infrared laser beam is between 500˜5000 W, so as to obtain the best welding and cladding effects.

### BACKGROUND OF THE INVENTION

### 1. Field of the Invention

The present invention relates to a kind of laser light processing, especially to one that makes laser light sources of two kinds of wavelengths combined through the optical fiber so that the output beams are coaxial and coincident to emit light, and the focus of the two wavelengths is generated by the optical assembly, so as to improve the stability of the laser processing process.

### 2. Description of the Related Art

Laser light has good directivity and concentration, and laser processing has no problems of tool wear and environmental pollution, therefore, metal welding with laser is an important issue in today's industrial manufacturing. However, high reflective metals such as copper, gold, silver, and aluminum have different surface absorptivity for laser light of various wavelengths at an absolute temperature of 295K, and the changing state is showing in FIG. 1; wherein, copper material (Cu) has surface absorption rate of 5% for near-infrared laser with a wavelength of about 1060 nm, and copper material (Cu) has surface absorption rate of 65% for blue ray laser with a wavelength of about 450 nm. Moreover, as showing in FIG. 2, which shows the application of infrared (IR) laser to heat copper, and the bistable phenomenon of material temperature relative to laser power; wherein, when the copper reaches the melting point, its melting temperature (absorption rate) will increase 5 time, at this time, the power of the infrared laser must be quickly reduced to avoid the surface temperature from entering the boiling area; at this time, although there is a molten pool (liquid metal) on the surface, due to changes in the power of the laser, it is also possible to cause molten pool interruption, thus affecting the stability of the welding process. Obviously, if using the infrared laser to weld copper materials, it is easy to cause poor quality problems such as molten pool interruption and spattering.

In recent years, there has been a trend in the world to replace infrared lasers with blue ray lasers for copper sheet welding; but blue ray lasers are composed of many blue ray semiconductor laser beams, and the higher the power, the more semiconductor lasers that need to be combined, the laser beams quality will decrease accordingly; For example, the laser beam parameter product (BPP) of a 500 W blue ray laser is as high as 40 mm*mrad, because the depth of field of the laser beam is too small, it is impossible to weld copper plates with a thickness greater than 1 mm; Also, the quality state of the laser beam can be measured by the beam parameter product (BPP), as showing in FIG. 3, wherein the value of BPP is obtained by the product of the divergence angle α of the laser beam and the radius R of the narrowest point of the laser beam; therefore, the value of BPP can not only quantify the quality of the laser beam, but also measure the degree to which the laser beam is focused to a small point; since the BPP value of the semiconductor laser is higher than 10 in the high power state, it will make the propagation characteristics of the beam and transform characteristic be restricted.

Based on the above-mentioned problems, the industry also uses hundreds of watts of blue ray lasers and kilowatts of optical fiber lasers for spatial beam combining, but the cost is high, and the spatial beam combining requires precise adjustment of optical lenses, so it has the disadvantage of poor stability. Its practicality has been questioned by the industry.

Thus, the inventors of the present invention realized that if two laser light sources with different wavelengths, blue laser and fiber laser, can be used to focus the combined laser beam on the welding area while reducing the laser output power and BPP value, it should be possible to further improve the process stability of brazing; however, how to achieve the benefits of this solution has become a topic of this present invention.

### SUMMARY OF THE INVENTION

It is a primary objective of the present invention to provide a fiber output hybrid laser system, which combines high-brightness blue ray laser model and infrared optical fiber laser, and output from one optical fiber.

Another objective of the present invention is to enable the output beam to effectively increase the absorption of copper metal, and has a relatively high beam quality and low processing cost, thereby improving the stability of the copper welding process.

In order to achieve the above objectives, the present includes at least a blue ray laser model, emitting a blue ray laser beam through a blue ray optic fiber; an infrared optic fiber laser module, emitting an infrared laser beam through an infrared optic fiber; a fiber bundle, which being used for embedding the blue ray optic fiber and the infrared optic fiber, and emitting an output light beam through an output optic fiber; an output optical assembly having a collimating lens and a focusing lens arranged at front and back, wherein the collimating lens is used to form the output light beam into a collimated parallel beam; and the focusing lens will make the passing parallel beam generating focal points of two wavelengths, which are a first focus and a second focus; and the output light beam generated by the output fiber, including the blue ray laser beam and the infrared laser beam which are coaxial and coincident to emit light, and the BPP of the blue ray laser beam and the infrared laser beam are both less than 10 mm*mrad; and through the adjustment of the focusing lens, the first focus of the blue ray laser beam will be formed on the surface of a material to be processed, and the second focus of the infrared laser beam will be penetrate into the material to be processed, and the distance between the first focus and the second focus is 1-3 mm, so as to obtain the best welding and cladding effects.

Also, the blue ray laser model has at least 7 blue ray laser diodes to excite at least 7 blue ray light beams with a wavelength of 400 nm˜670 nm, an optical lens assembly, including at least 7 fast axis collimating lenses, slow axis collimating lenses, reflecting lenses and a focusing lens, so that the individual blue ray light beams are respectively collimated through each of the fast axis collimating lenses and each of the slow axis collimating lenses, and after passing through each of the reflecting lenses, then combined into a blue ray laser beam, and the blue ray laser beam can be coupled into the core of the blue ray optic fiber through the action of the focusing lens.

Also, the infrared optical fiber laser module having a seeding light source device, which uses an infrared laser diode to emit a seeding laser beam with a wavelength of 1064 nm, and an excitation light source device, which uses a high-power semiconductor laser, so as to emit an excitation laser beam with a wavelength of 800˜980 nm, a beam combiner, which is used to couple the seeding laser beam and the excitation laser beam into the core of the infrared optical fiber, so as to form the infrared laser beam, and a fiber amplifier amplifies the energy of the infrared laser beam.

Also, the output optic has a core diameter of 100 μm and a cladding of 300 μm.

Also, the blue ray laser beam in the output light beam having a wavelength between 400 nm˜480 nm, and the power is between 20˜100 W, and the infrared laser beam in the output light beam having a wavelength between 900 nm˜1100 nm, and the power is between 500˜5000 W.

With feature the disclosed above, the present invention uses at least one blue ray laser model and one infrared optic fiber laser module to emit a blue ray laser beam with a total power of less than 100 watts and infrared laser beam with a total power up to kilowatts; a fiber bundle combines the blue ray laser beams and infrared laser beams, and an output optical assembly collimates the beams and generates a focal point of two wavelengths; wherein, the output blue ray laser beam and infrared laser beam are coaxial and coincident to emit light, and the beam parameter product BPP is less than 10 mm*mrad; and the power of blue light is between 20˜100 W, and the power of infrared light is between 500˜ 5000 W, and the focus of blue light will be formed on the surface of the material to be processed, and the focus of infrared light will be 1-3 mm away from it and penetrate into the material to be processed, so as to obtain the best welding and layered cladding effect; the optical fiber used in the present invention compared with conventional spatial beam combining, the present invention has lower cost benefits; moreover, the beam parameter product BPP of the output blue ray laser beam and infrared laser beam is less than 10 mm*mrad, making the combined laser beam be focused on the welding area, and the beam quality is good, which will further improve the process stability of copper welding.

### BRIEF DESCRIPTION OF THE DRAWINGS

FIG. 1 is a graph of the absorptivity of conventional lasers with different wavelengths on various metal surfaces;

FIG. 2 a schematic diagram illustrating the bistable state of material temperature vs. laser power when copper is heated by conventional infrared rays;

FIG. 3 is a schematic diagram of the laser beam parameter product of a conventional laser beam;

FIG. 4 is a schematic diagram of the structure of a fiber output color mixing laser system of an embodiment of the present invention.

FIG. 5 is a schematic diagram of the segmental structure of the fiber bundle in the present invention;

FIG. 6 is a schematic diagram of the structure of the output collimating lens of the present invention;

FIG. 7 is a schematic diagram of the state of the dual-wavelength focal point of the present invention;

FIG. 8 is a schematic diagram of the structure of the blue ray laser model of the present invention;

FIG. 9 is a schematic diagram of the structure of the infrared optic fiber laser module of the present invention.

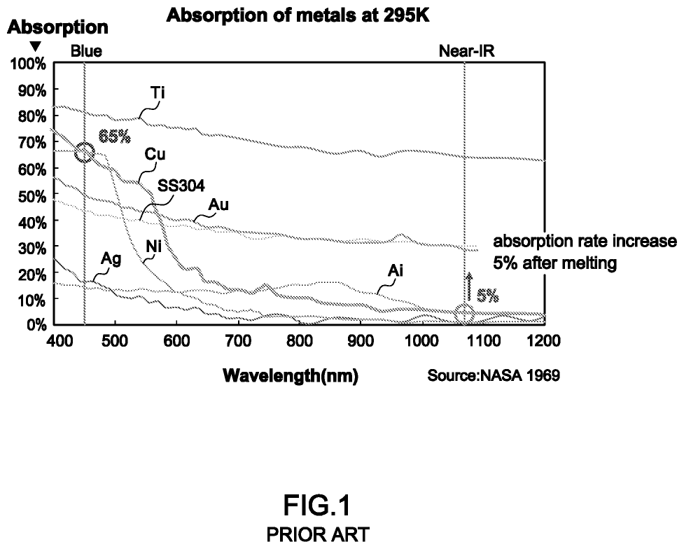

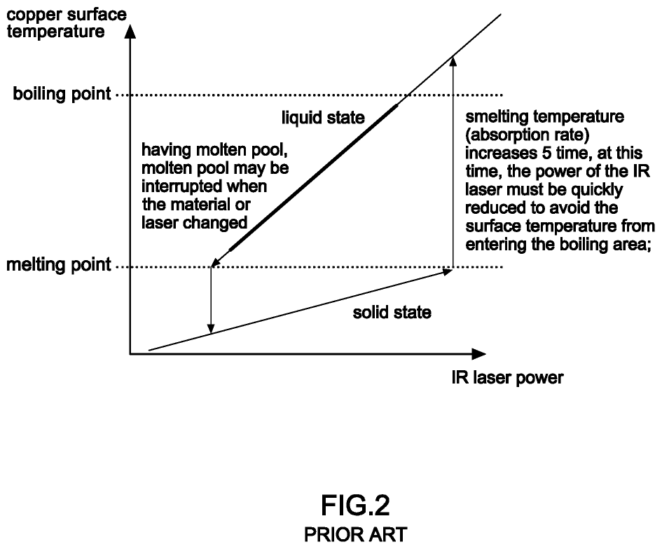

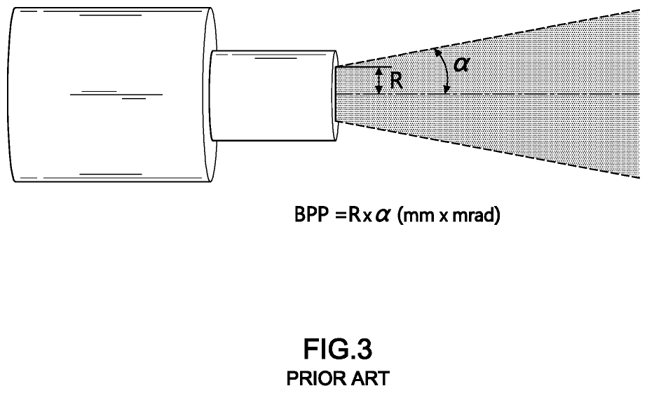

### DETAILED DESCRIPTION OF THE PREFERRED EMBODIMENT

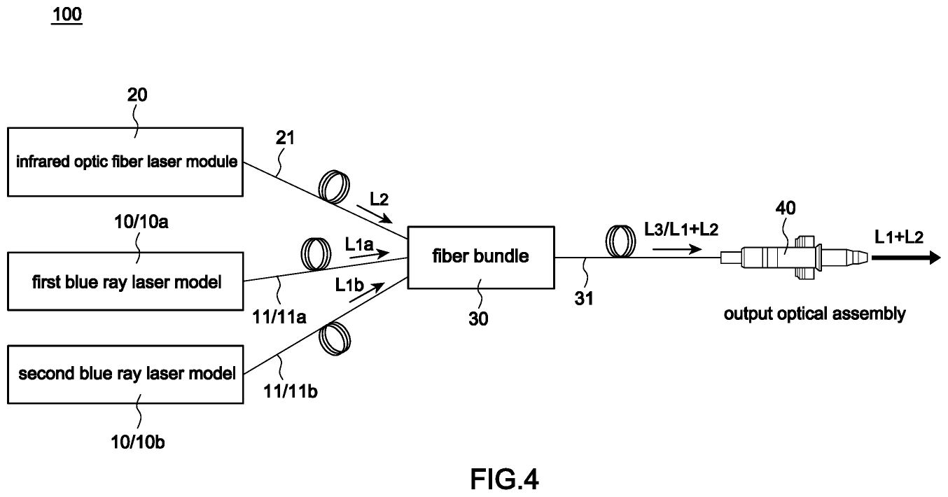

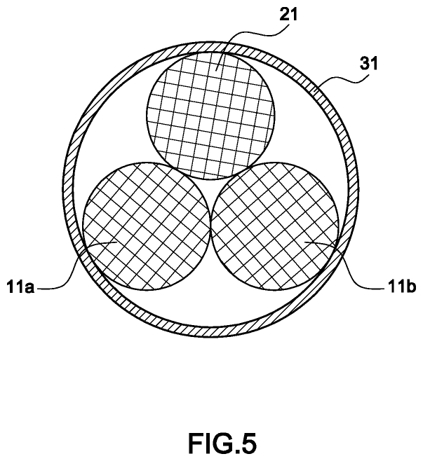

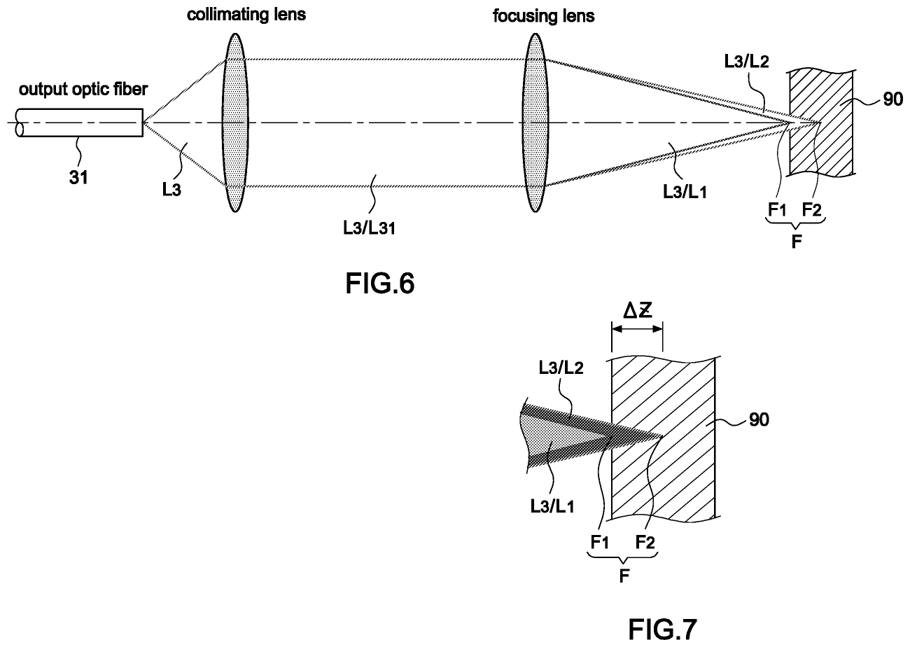

First, referring to FIG. 4, the present invention includes: at least a blue ray laser model 10, emitting a blue ray laser beam L1 through a blue ray optic fiber 11; in this embodiment, there two groups of the blue ray laser model 10, so this embodiment includes a first blue ray laser model 10a connected to a first blue ray optic fiber 11a to emit a first blue ray laser beam L1a, and a second blue ray laser model 10b is connected to a second blue ray optic fiber 11b to emit a second blue ray laser beam L1b; an infrared optic fiber laser module 20, emitting an infrared laser beam L2 through an infrared optic fiber 21; a fiber bundle 30, which being used for embedding the blue ray optic fiber 11 and the infrared optic fiber 21, and emitting an output light beam L3 through an output optic fiber 31, and the output optic fiber 31 has a core diameter of 100 μm and a cladding of 300 μm for generating a output light beam L3; in this embodiment, the fiber bundle 30 is embedded into the first blue ray optic fiber 11a, the second blue ray optic fiber 11b and the infrared optic fiber 21, as showing in FIG. 5; an output optical assembly 40, referring to FIG. 6, having a collimating lens 41 and a focusing lens 42 arranged at front and back, wherein the collimating lens 41 is used to form the output light beam L3 into a collimated parallel beam L31; and the focusing lens 42 will make the passing parallel beam L31 generating focal points F of two wavelengths, which are a first focus F1 and a second focus F2; and the output light beam L3 generated by the output fiber 31, including the blue ray laser beam L1, the wavelength of the blue ray laser beam L1 is between 400 nm˜480 nm, and the power is between 20˜100 W, and the infrared laser beam L2, the wavelength of the infrared laser beam L2 is between 900 nm˜1100 nm, and the power is between 500˜5000 W; the blue ray laser beam L1 and the infrared laser beam L2 are coaxial and coincident to emit light, and the BPP of the blue ray laser beam L1 and the infrared laser beam L2 are both less than 10 mm*mrad; and through the adjustment of the focusing lens 42, the first focus F1 of the blue ray laser beam L1 will be formed on the surface of a material 90 to be processed, and the second focus F2 of the infrared laser beam L2 will be penetrate into the material 90 to be processed, and the distance ΔZ between the first focus F1 and the second focus F2 is 1-3 mm, as FIG. 7 showing, so as to obtain the best welding and cladding effects.

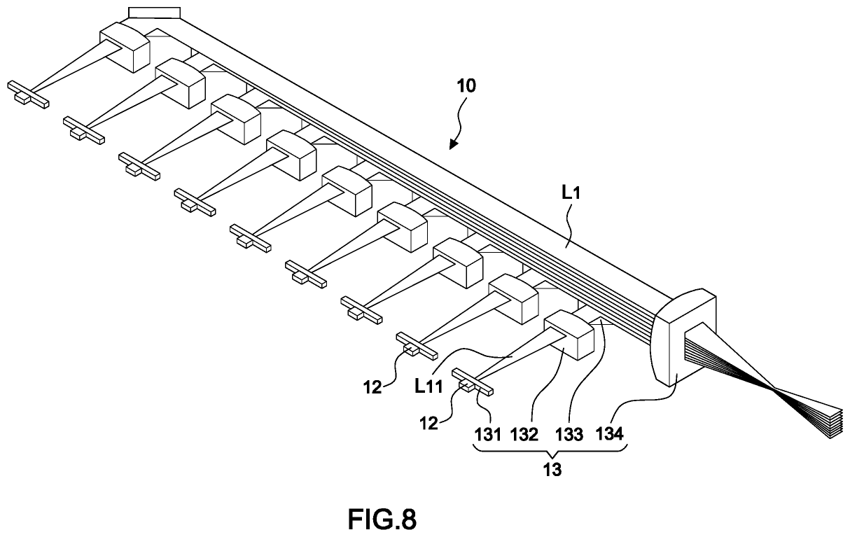

The blue ray laser model 10 of the present invention has at least 7 blue ray laser diodes 12, as FIG. 8 showing; in this embodiment having 9 blue ray laser diodes 12, to excite 9 blue ray light beams L11 with a wavelength of 400 nm˜670 nm, an optical lens assembly 13, including at least 7 fast axis collimating lenses 131, slow axis collimating lenses 132, reflecting lenses 133, in this embodiment 9 lenses for each and a focusing lens 134, so that the individual blue ray light beams L11 are respectively collimated through each of the fast axis collimating lenses 131 and each of the slow axis collimating lenses 132, and after passing through each of the reflecting lenses 133, then combined into a blue ray laser beam L1, and the blue ray laser beam L1 can be coupled into the core of the blue ray optic fiber 11 through the action of the focusing lens 134.

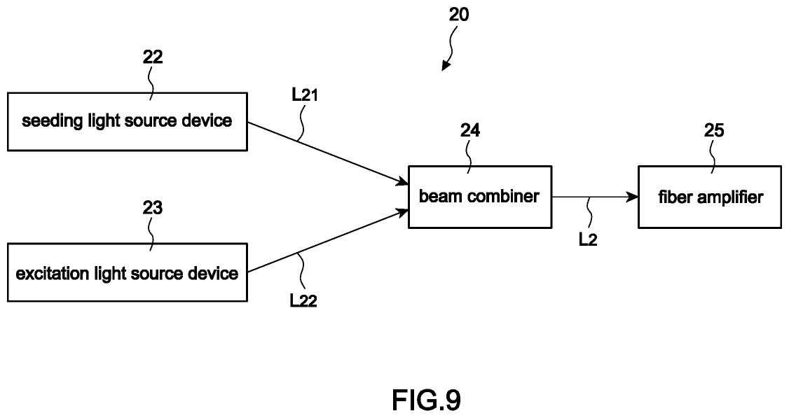

Referring to FIG. 9, the infrared optical fiber laser module 20 of the present invention having a seeding light source device 22, which uses an infrared laser diode to emit a seeding laser beam L21 with a wavelength of 1064 nm, and an excitation light source device 23, which uses a high-power semiconductor laser, so as to emit an excitation laser beam L22 with a wavelength of 800˜980 nm, a beam combiner 24, which is used to couple the seeding laser beam L21 and the excitation laser beam L22 into the core of the infrared optical fiber 21, so as to form the infrared laser beam L2, and a fiber amplifier 25 amplifies the energy of the infrared laser beam.

The present invention uses at least one blue ray laser model 10 and one infrared optic fiber laser module 20 to emit a blue ray laser beam L1 with a total power of less than 100 watts and infrared laser beam L2 with a total power up to kilowatts; a fiber bundle 30 combines the blue ray laser beams L1 and infrared laser beams L2, and an output optical assembly 40 collimates the beams and generates a focal point F of two wavelengths; wherein, the output blue ray laser beam L1 and infrared laser beam L2 are coaxial and coincident to emit light, and the beam parameter product BPP is less than 10 mm*mrad; and the power of blue light is between 20˜100 W, and the power of infrared light is between 500˜ 5000 W, and the first focus F1 of blue light will be formed on the surface of the material 90 to be processed, and the second focus F2 of infrared light will be 1˜3 mm away from it and penetrate into the material 90 to be processed, so as to obtain the best welding and layered cladding effect; the optical fiber used in the present invention compared with conventional spatial beam combining, the present invention has lower cost benefits; moreover, the beam parameter product BPP of the output blue ray laser beam L1 and infrared laser beam L2 is less than 10 mm*mrad, making the combined laser beam be focused on the welding area, and the beam quality is good, which will further improve the process stability of copper welding.

Although particular embodiments of the invention have been described in detail for purposes of illustration, various modifications and enhancements may be made without departing from the spirit and scope of the invention. Accordingly, the invention is not limited except as by the appended claims.

What is claimed is:

1. A fiber output hybrid laser system, comprising:
at least a blue ray laser model, emitting a blue ray laser beam through a blue ray optic fiber;
an infrared optic fiber laser module, emitting an infrared laser beam through an infrared optic fiber;
a fiber bundle, which being used for embedding the blue ray optic fiber and the infrared optic fiber, and emitting an output light beam through an output optic fiber;
an output optical assembly having a collimating lens and a focusing lens arranged at front and back, wherein the collimating lens is used to form the output light beam into a collimated parallel beam; and the focusing lens will make the passing parallel beam generating focal points of two wavelengths, which are a first focus and a second focus; and
the output light beam generated by the output fiber, including the blue ray laser beam and the infrared laser beam which are coaxial and coincident to emit light, and the BPP of the blue ray laser beam and the infrared laser beam are both less than 10 mm*mrad; and through the adjustment of the focusing lens, the first focus of the blue ray laser beam will be formed on the surface of a material to be processed, and the second focus of the infrared laser beam will be penetrate into the material to be processed, and the distance between the first focus and the second focus is 1-3 mm, so as to obtain the best welding and cladding effects.

2. The fiber output hybrid laser system as claimed in claim 1, wherein the blue ray laser model has at least 7 blue ray laser diodes to excite at least 7 blue ray light beams with a wavelength of 400 nm˜670 nm, an optical lens assembly, including at least 7 fast axis collimating lenses, slow axis collimating lenses, reflecting lenses and a focusing lens, so that the individual blue ray light beams are respectively collimated through each of the fast axis collimating lenses and each of the slow axis collimating lenses, and after passing through each of the reflecting lenses, then combined into a blue ray laser beam, and the blue ray laser beam can be coupled into the core of the blue ray optic fiber through the action of the focusing lens.

3. The fiber output hybrid laser system as claimed in claim 1, wherein the infrared optical fiber laser module having a seeding light source device, which uses an infrared laser diode to emit a seeding laser beam with a wavelength of 1064 nm, and an excitation light source device, which uses a high-power semiconductor laser, so as to emit an excitation laser beam with a wavelength of 800˜980 nm, a beam combiner, which is used to couple the seeding laser beam and the excitation laser beam into the core of the infrared optical fiber, so as to form the infrared laser beam, and a fiber amplifier amplifies the energy of the infrared laser beam.

4. The fiber output hybrid laser system as claimed in claim 1, wherein the output optic fiber has a core diameter of 100 μm and a cladding of 300 μm.

5. The fiber output hybrid laser system as claimed in claim 1, wherein the blue ray laser beam in the output light beam having a wavelength between 400 nm˜480 nm, and the power is between 20˜100 W, and the infrared laser beam in the output light beam having a wavelength between 900 nm˜1100 nm, and the power is between 500˜5000 W.
